(19) United States
(12) Patent Application Publication
(10) Pub. No.: US 2010/0159708 A1
(43) Pub. Date: Jun. 24, 2010

(54) Method for forming required pattern on semiconductor substrate by thermal reflow technique

(75) Inventors: Yi Edward Chang, Hsinchu (TW); Chia-Ta Chang, Hsinchu (TW); Shih-Kuang Hsiao, Hsinchu (TW)

Correspondence Address: BACON & THOMAS, PLLC, 625 SLATERS LANE, FOURTH FLOOR, ALEXANDRIA, VA, 22314-1176, US

(73) Assignee: National Chiao Tung University, Hsinchu (TW)

(21) Appl. No.: 12/385,525

(22) Filed: Apr. 10, 2009

(30) Foreign Application Priority Data
Dec. 22, 2008 (TW) 097149988

(51) Int. Cl. H01L 21/3065

(52) U.S. Cl. 438/719; 438/710; 438/722; 257/E21.218; 257/E21.231

(57) ABSTRACT

The invention is disclosed that pattern on semiconductor substrate is fabricated by thermal reflow technique. Also, the pattern on semiconductor substrate having different sub-micron spacings can be fabricated by using different time for the thermal reflow technique process.

### BACKGROUND OF THE INVENTION

1. Field of the Invention

The invention relates to a method for forming required pattern on semiconductor substrate, particularly to a method for forming required pattern on semiconductor substrate by thermal reflow technique.

2. Description of the Prior Art

Conventionally, when the required pattern is formed on the semiconductor substrate, the dry etching method will be used to form the required pattern. Although the dry etching method can form the required pattern with high density and high aspect ratio, the dry etching method it is unable to etch the pattern to form as tilt angle, and the etched contour cannot to be become as smooth, level and uniform cylinder pattern.

As conventional formation method for patterning of semiconductor substrate, the prior art is shown in FIG. 1A, FIG. 1B and FIG. 1C. As shown in FIG. 1A, the hard mask 102 is formed on the semiconductor substrate 101. And as shown in FIG. 1B, the photo-resist layer 103 is formed on the hard mask 102. Finally, as shown in FIG. 1C, the dry etching method is used to etch the semiconductor substrate 101 by removing the hard mask 102 through the photo-resist layer 103, in order to form the required pattern. The pattern of semiconductor substrate etched by the prior art can not have specific tilt angle and level contour.

When the semiconductor substrate has specific tilt angle, such as the etched cylindrical pattern, if it is used to LED component, it will increase the external extraction efficiency of light, and raise the output power of the component.

In addition, although the wet etching method can etch the pattern with tilt angle on semiconductor substrate, the wet etching method cannot etch the pattern to become as smooth, level and uniform cylinder pattern.

As prior art specified in Taiwan Patent No. 1236773, the pattern formed on the semiconductor substrate is the hole-shape pattern. Thus, the pattern density and aspect ratio are pretty low, and there is no specific cylindrical and tilt angle.

As prior art specified in Taiwan Patent No. 200601582, the formation method for the pattern of semiconductor substrate is the same as above method. Thus, the pattern density and aspect ratio are pretty low, and there is no specific cylindrical and tilt angle.

Therefore in the published literature at present, the dry etching method can not etch the pattern on semiconductor substrate with tilt angle, high density, high aspect ratio, and it is unable to etch the pattern as cylinder having smooth and level contour. This result will influence the quality of epitaxy grown on the semiconductor substrate and the characteristics applied on the component seriously.

Thus, in order to respond the production requirement of pattern semiconductor substrate technology, it is necessary to develop relevant manufacturing technology, and save the manufacturing manpower and manufacturing time, and form various types of required pattern on semiconductor substrates effectively, to achieve the goal of energy saving and carbon reduction

### SUMMARY OF THE INVENTION

The invention relates to a method for forming required pattern on semiconductor substrate by thermal reflow technique.

Compared to the pattern on semiconductor substrate of the prior art, the invention can form the pattern having high density, high aspect ratio, and tilt angle, and the cylinder having smooth, level and uniform contour. Thus, it can increase the characteristics of the component greatly.

The invention can form the semiconductor substrate having different spacing of pattern, and form the semiconductor substrate having extremely small line width by controlling the time of thermal reflow treatment.

The invention can improve the photolithography technique of semiconductor process, and improve the etched pattern of semiconductor substrate, change the shape of photo-resist by controlling the time of thermal reflow treatment further, thus it can narrow down the spacing of pattern on semiconductor substrate.

The invention can reduce the dislocation density of epitaxy and raise the quality of epitaxy. As for the LED component, the invention can increase the external extraction efficiency of light, and raise the output power of the component.

The advantage and spirit of the invention can be understood further by the following detail description of invention and attached Figures.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A to FIG. 1C show the diagram of the prior art.

FIG. 2A to FIG. 2D show the preferred embodiment of the invention.

FIG. 3 shows the electron microscope diagram.

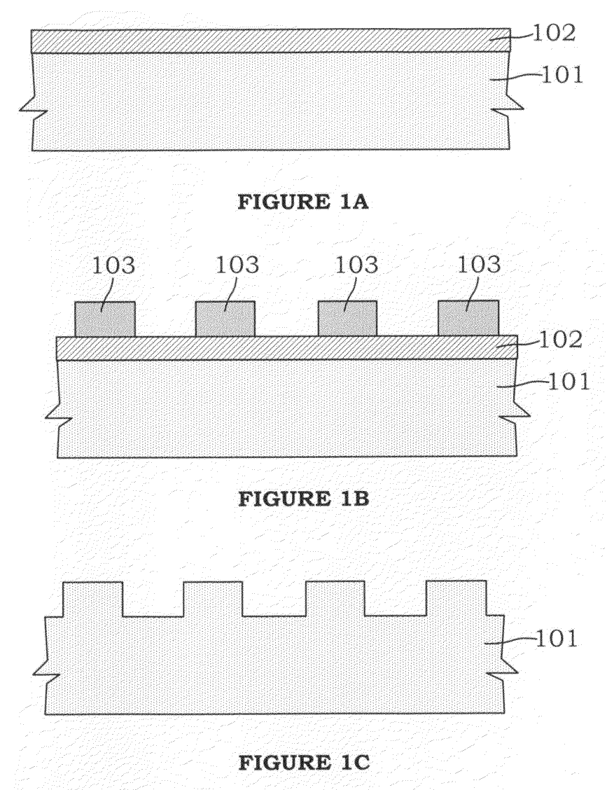

### DESCRIPTION OF THE PREFERRED EMBODIMENT

The invention relates to a method for forming pattern on semiconductor substrate by thermal reflow technique, the detailed steps are described as follows:

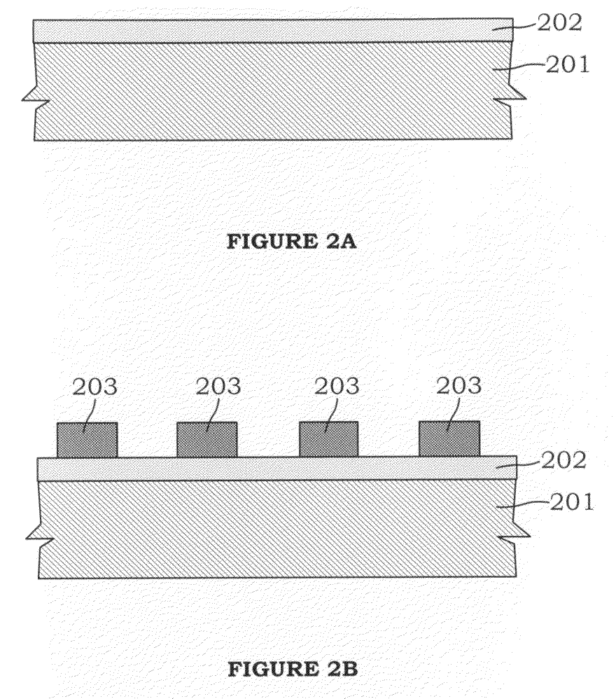

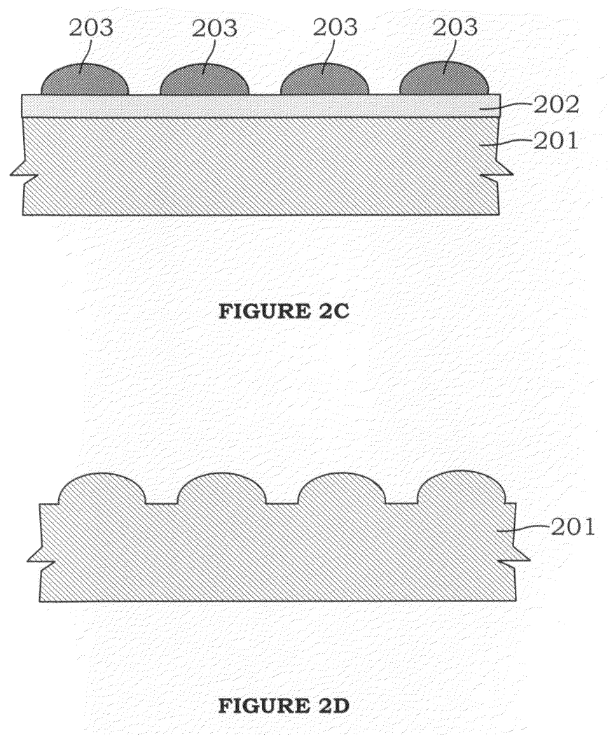

The invention uses thermal reflow technique to form circular pattern on semiconductor substrate. The process is shown in FIG. 2A to FIG. 2D.

As shown in FIG. 2A, the hard mask 202 is formed on the semiconductor substrate 201. The material of semiconductor substrate includes Sapphire, silicon (Si), and silicon carbide (SiC) etc.

As shown in FIG. 2B, the photoresist layer 203 is formed on the hard mask 202.

As shown in FIG. 2C, the photoresist layer 203 is treated by thermal reflow technique, so that the shape of photoresist layer 203 is changed to become as a circular shape for the photoresist layer 203. The temperature of thermal reflow treatment is about 150° C. to 180° C. The time of thermal reflow treatment is controlled at 30 seconds to 120 seconds, in order to form the pattern as different drawn spacing for photoresist layer 203.

As shown in FIG. 2D, the dry etching method in the photolithography technique of semiconductor process, such as the plasma etching method is used to etch the semiconductor substrate 201 by removing the hard mask 202 through the photoresist layer 203, in order to form the circular pattern on semiconductor substrate 201. Thus the pattern on semiconductor substrate 201 is formed as high density, high aspect ratio, and tilt angle, and the cylinder with smooth, level and uniform contour. The line width of pattern can be minimized to 0.3 μm to 1 μm.

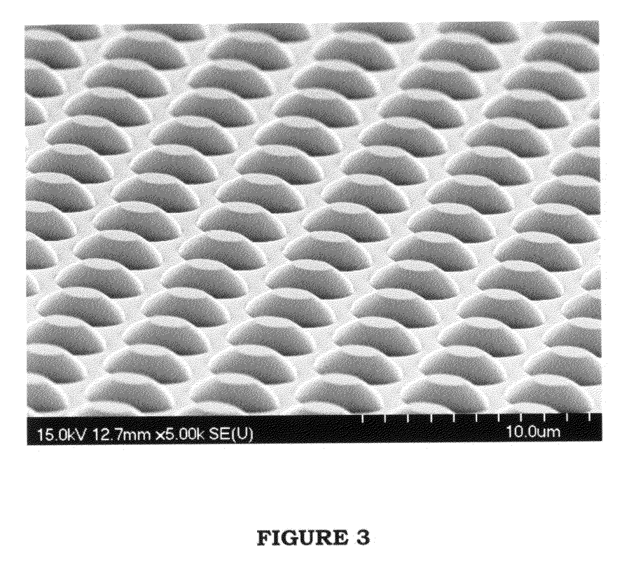

FIG. 3 shows the etched result of sapphire semiconductor substrate observed under the electron microscope, and the etching contour is like as level, uniform and tilt angle.

The invention is a technique to improve the photolithography process. The dry etching method is used to etch the semiconductor substrate to form the pattern with high density, high aspect ratio, and tilt angle, and the cylinder with smooth, level and uniform contour. The invention can form the semiconductor substrate having different drawn spacing of pattern, and can form the semiconductor substrate having extremely small line width by controlling the time of thermal reflow treatment.

Compared to the pattern on semiconductor substrate of the prior art, the invention can form the pattern with high density, high aspect ratio, and tilt angle, and the cylinder with smooth, level and uniform contour. The invention can form the semiconductor substrate having different drawn spacing of pattern, and formed on the semiconductor substrate having extremely small line width by controlling the time of thermal reflow treatment.

It is understood that various other modifications will be apparent to and can be readily made by those skilled in the art without departing from the scope and spirit of this invention. Accordingly, it is not intended that the scope of the claims appended hereto be limited to the description as set forth herein, but rather that the claims be construed as encompassing all the features of patentable novelty that reside in the present invention, including all features that would be treated as equivalents thereof by those skilled in the art to which this invention pertains.

What is claimed is:

1. A method for forming a specific pattern on semiconductor substrate using a thermal reflow technique, comprising:
forming a hard mask on a semiconductor substrate and the hard mask having a photoresist layer thereon;
treating the photoresist layer by a thermal reflow technique to form as a specific-shape photoresist layer; and
etching the semiconductor substrate by removing the hard mask through the photoresist layer in order to form the specific pattern on the semiconductor substrate.

2. The method according to claim 1, wherein the semiconductor substrate comprises sapphire.

3. The method according to claim 1, wherein the semiconductor substrate comprises silicon.

4. The method according to claim 1, wherein the semiconductor substrate comprises silicon carbide.

5. The method according to claim 1, wherein a temperature for the thermal reflow treatment comprises about 150° C. to 180° C.

6. The method according to claim 1, wherein a time for the thermal reflow treatment is controlled at 30 seconds to 120 seconds.

7. The method according to claim 1, wherein the dry etching method comprises plasma etching method.

8. The method according to claim 1, wherein the pattern comprises a line width.

9. The method according to claim 8, wherein the line width comprises about 0.3 μm to 1 μm.

10. A method for forming a specific pattern on semiconductor substrate using a thermal reflow technique, comprising:
forming a hard mask on a semiconductor substrate;
forming a photoresist layer on the hard mask;
treating the photoresist layer by a thermal reflow technique to form a specific-shape photoresist layer; and
etching the semiconductor substrate by removing the hard mask through the photoresist layer in order to form the specific pattern on semiconductor substrate.

11. The method according to claim 10, wherein the semiconductor substrate comprises sapphire.

12. The method according to claim 10, wherein the semiconductor substrate comprises silicon.

13. The method according to claim 10, wherein the semiconductor substrate comprises silicon carbide.

14. The method according to claim 10, wherein a temperature for the thermal reflow treatment comprises about 150° C. to 180° C.

15. The method according to claim 10, wherein a time for the thermal reflow treatment is controlled at 30 seconds to 120 seconds.

16. The method according to claim 10, wherein the dry etching method comprises plasma etching method.

17. The method according to claim 10, wherein the specific pattern comprises a line width.

18. The method according to claim 17, wherein the line width comprises about 0.3 μm to 1 μm.
